(19) United States
(12) Patent Application Publication
(10) Pub. No.: US 2005/0266665 A1
(43) Pub. Date: Dec. 1, 2005

(54) Methods of manufacturing semiconductor devices with gate structures having an oxide layer on the sidewalls thereof and related processing apparatus

(76) Inventors: Sun-Pil Youn, Seoul (KR); Gil-Heyun Choi, Gyeonggi-do (KR); Chang-Won Lee, Gyeonggi-do (KR); Byung-Hak Lee, Gyeonggi-do (KR); Hee-Sook Park, Seoul (KR); Woong-Hee Shon, Gyeonggi-do (KR); Jong-Ryeol Yoo, Gyeonggi-do (KR)

Correspondence Address: MYERS BIGEL SIBLEY & SAJOVEC, PO BOX 37428, RALEIGH, NC, 27627, US

(21) Appl. No.: 11/141,401

(22) Filed: May 31, 2005

(30) Foreign Application Priority Data
May 31, 2004 (KR) 2004-38809

(51) Int. Cl. H01L 21/3205

(52) U.S. Cl. 438/592

(57) ABSTRACT

In a method of manufacturing a semiconductor device, a gate structure having a conductive layer pattern is formed on a substrate. The gate structure is then annealed. Oxygen radicals are applied to the gate structure to form an oxide layer on a sidewall of the conductive layer pattern.

### CROSS REFERENCE TO RELATED APPLICATION

This application claims priority under 35 U.S.C. § 119 Application No. 2004-38809, filed on May 31, 2004, the disclosure of which is hereby incorporated by reference herein as if set forth in its entirety.

### FIELD OF THE INVENTION

The present invention relates to semiconductor devices and, more particularly, to methods of forming semiconductor devices with improved gate structures and apparatus that may be used in carrying out these methods.

### BACKGROUND OF THE INVENTION

The peripheral circuits of many conventional dynamic random access memory (DRAM) semiconductor devices and other semiconductor circuits include a complementary metal-oxide-semiconductor (CMOS) structure that has an NMOS transistor and a PMOS transistor. In these above-mentioned applications, N⁺ type polysilicon is often used to form the gate electrodes of both the NMOS transistor and the PMOS transistor. Semiconductor circuits with such a CMOS structure may tend to exhibit low power consumption, fast operation speed, sufficient noise margin, high reliability and other desirable characteristics.

To form the polysilicon gate electrodes for the above-mentioned devices, a gate oxide layer is formed on a semiconductor substrate. A polysilicon layer, a metal layer and a hard mask layer are then sequentially formed on the gate oxide layer. The polysilicon layer, the metal layer and the hard mask layer are then etched to form a gate structure that includes a polysilicon pattern, a metal pattern and a hard mask pattern. During this etching process, the gate oxide layer may be damaged in that micro-trenches may be formed partially or completely through the gate oxide layer. These micro-trenches may act as passageways for leakage currents. Accordingly, the micro-trenches may reduce the insulating capacity of the gate oxide layer. Also, when the gate oxide layer and the polysilicon layer are partially removed during the etching process, the thickness of the gate oxide layer is reduced. This thinning of the gate oxide layer may also act to reduce the overall performance of the semiconductor device.

In order cure the micro-trench damage to the gate oxide layer and to make sure that the etched gate oxide layer has a thickness within a desired range, the metal pattern and the gate oxide layer may be re-oxidized. One conventional method for implementing this re-oxidation process is to place the substrate having the gate structure into a furnace or a rapid thermal process (RTP) chamber, and then heating the substrate at a temperature of about 700° C. or more in an oxygen atmosphere. When the re-oxidation process is completed, an oxide layer is formed on a sidewall of the metal pattern and the thickness of the gate oxide layer is increased. However, this conventional re-oxidation process may cause a rapid increase in the volume of the polysilicon pattern and/or the metal pattern. When this occurs, the sheet resistance of the gate electrode may be increased. In some instances, the metal pattern may be lifted so that the electrical connection in the gate electrode is broken.

In an effort to prevent the above-mentioned problems, a selective oxidation process may be used in place of the above-described oxidation process. In this selective oxidation process, only a sidewall of the polysilicon layer pattern is oxidized. In such a selective oxidation process, the substrate is oxidized in a hydrogen-rich atmosphere at a temperature of 700° C. or more so that only the polysilicon pattern and the gate oxide layer are oxidized. However, conventional selective oxidation processes may cause a significant increase in the thickness of the gate oxide layer. When the thickness of the gate oxide layer exceeds a certain level, the operational reliability of the gate electrode may start to deteriorate.

In an effort to prevent the above-described problems with conventional selective oxidation techniques, re-oxidation processes that use oxygen radicals are sometimes used which are carried out at a temperature of no more than about 250° C. The use of this relatively low-temperature re-oxidation process may reduce or eliminate the tendency of the gate oxide layer to increase in thickness beyond a desired range. However, the low temperature re-oxidation process may not be as effective in curing the damage to the gate oxide layer and/or the damage to the channel region under the gate oxide layer.

A conventional method of curing damage to the channel region and to the gate oxide layer in the gate structure of a CMOS device is disclosed in Korean Patent Laid Open Publication No. 2003-0093449. FIGS. 1 to 3 herein are cross sectional diagrams illustrating the conventional method in Korean Patent Laid Open Publication No. 2003-0093449.

As shown in FIG. 1, in the conventional gate formation method, a gate oxide layer 12 is formed on a semiconductor substrate 11. A portion of the semiconductor substrate 11 under the gate oxide layer 12 acts as a channel region. A polysilicon layer (not shown), a diffusion barrier layer (not shown), a metal layer (not shown) and a hard mask layer (not shown) are sequentially formed on the gate oxide layer 12. The polysilicon layer, the diffusion barrier layer, the metal layer and the hard mask layer are then etched to form a gate structure that includes the gate oxide layer 12, a polysilicon pattern 13, a diffusion barrier pattern 14, a metal pattern 15 and a hard mask pattern 16. Both the channel region and the gate oxide layer 12 may be damaged in this etching process.

As shown in FIG. 2, oxygen radicals are then applied to the gate structure and the semiconductor substrate 11. Typically, the oxygen radicals are deposited at a temperature of about 250° C. to about 400° C. As shown in FIG. 3, the oxygen radicals cause an oxide layer 17 to form on the sidewalls of the polysilicon pattern 13, the diffusion barrier pattern 14 and the metal pattern 15. The semiconductor substrate 11 is then thermally treated at a temperature of 600° C. or more in a nitrogen atmosphere to cure the damage to the channel region and to the gate oxide layer 12.

### SUMMARY OF THE INVENTION

Pursuant to embodiments of the present invention, methods of manufacturing semiconductor devices are provided in which a gate structure having a conductive pattern is formed on a substrate. The gate structure is then annealed, and oxygen radicals are then applied to the annealed gate structure to form an oxide layer on a sidewall of the conductive pattern. In certain embodiments of these methods, the gate structure may be formed by forming a gate oxide layer on a substrate, and then forming the conductive pattern on the gate oxide layer. The conductive pattern may be formed, for example, by forming a polysilicon pattern on the gate oxide layer, and then forming a metal pattern on the polysilicon pattern, and then forming a hard mask pattern on the metal pattern. In these embodiments, the oxide layer may be formed on a sidewall of the polysilicon pattern.

In specific embodiments of the present invention, the metal pattern may comprise, for example, tungsten, tungsten silicide, cobalt silicide or nickel silicide. The hard mask pattern may comprise, for example, tungsten nitride. The gate structure may be annealed at a temperature of no less than about 600° C. The annealing atmosphere may include, for example, at least one of a nitrogen gas, a hydrogen gas, and/or an argon gas. The oxygen radicals may be applied to the gate structure at a temperature of no more than about 250° C. Moreover, the annealing of the gate structure and/or the forming of the oxide layer may be performed in-situ under vacuum.

Pursuant to further embodiments of the present invention, gate structures may be formed by forming a gate oxide layer on a substrate, and then sequentially forming a polysilicon layer, a tungsten layer and a tungsten nitride layer on the gate oxide layer. The polysilicon layer, the tungsten layer and the tungsten nitride layer may then be patterned to form a gate structure that includes a polysilicon pattern, a tungsten pattern and a tungsten nitride pattern. After this patterning is completed, the gate structure may be annealed in an atmosphere that includes at least one inert gas. Then, oxygen radicals may be applied to the annealed gate structure to form an oxide layer on a sidewall of the polysilicon pattern.

In still further embodiments of the present invention, methods of manufacturing semiconductor devices are provided in which an annealing unit is heated to a first temperature using a lamp located within the annealing unit. A gate structure that has been formed on a substrate may then be annealed in the annealing unit at the first temperature. Thereafter, oxygen radicals may be applied to the gate structure at a second temperature that is lower than the first temperature to form an oxide layer on a sidewall of the conductive pattern.

In certain specific embodiments of these methods, the oxygen radicals may be applied to the gate structure in a re-oxidation unit that is separate from the annealing unit. This re-oxidation unit may first be heated to the second temperature using a heater. The method may also include transferring the gate structure that has been formed on the substrate from the annealing unit after the annealing is completed to the re-oxidation unit for application of the oxygen radicals via a vacuum chamber that is coupled between the annealing unit and the re-oxidation unit. In other embodiments, the step of applying oxygen radicals to the gate structure at a second temperature that is lower than the first temperature to form an oxide layer on a sidewall of the conductive pattern may be accomplished by heating the annealing unit to the second temperature using a heater arranged at a lower portion of the chamber and then applying oxygen radicals to the gate structure.

An apparatus for manufacturing a semiconductor device in accordance with still another aspect of the present invention includes a first processing unit for annealing a substrate on which a gate structure having a conductive layer pattern is formed at a first temperature. A second processing unit applies oxygen radicals to an annealed substrate at a second temperature that is lower than the first temperature to partially form an oxide layer on a sidewall of the conductive pattern.

An apparatus for manufacturing a semiconductor device in accordance with still another aspect of the present invention includes a chamber for receiving a substrate on which a gate structure having a conductive layer pattern is formed. A lamp is arranged over the chamber. The lamp heats the substrate to a first temperature to annealing the gate structure. A heater is arranged in a lower portion of the chamber. The heater heats an annealed substrate to a second temperature that is lower than the first temperature to form an oxide layer on a sidewall of the conductive layer pattern using oxygen radicals that are introduced into the chamber.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIGS. 1 to 3 are cross sectional diagrams illustrating a conventional method of manufacturing a semiconductor device;

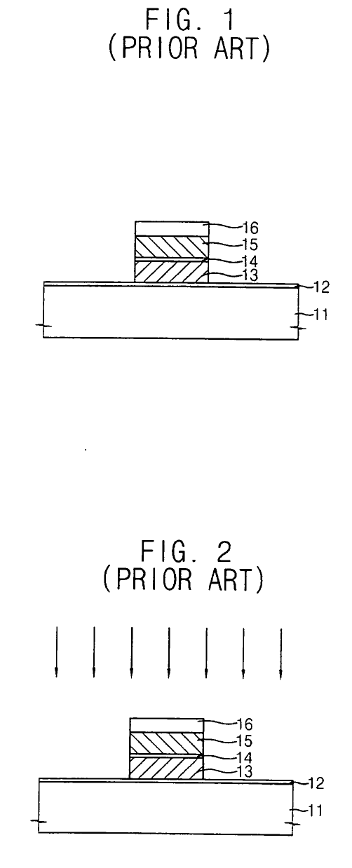

FIGS. 4 to 7 are cross sectional diagrams illustrating methods of manufacturing semiconductor devices in accordance with certain embodiments of the present invention;

FIG. 8 is a schematic view illustrating an apparatus for manufacturing the semiconductor device in FIG. 7 in accordance with one embodiment of the present invention;

FIG. 9 is a cross sectional diagram illustrating a first processing unit of the apparatus in FIG. 8;

FIG. 10 is cross sectional diagram illustrating a second processing unit of the apparatus in FIG. 8;

FIG. 11 is a cross sectional diagram illustrating an apparatus for manufacturing the semiconductor device in FIG. 7 in accordance with another embodiment of the present invention;

FIG. 12 is a scanning electron microscope (SEM) picture illustrating a gate structure fonned by a method in accordance with Comparative Example 1;

FIG. 13 is a scanning electron microscope (SEM) picture illustrating a gate structure formed by a method in accordance with Comparative Example 2;

FIG. 14 is a scanning electron microscope (SEM) picture illustrating a gate structure formed by a method in accordance with Comparative Example 3;

FIG. 15 is a scanning electron microscope (SEM) picture illustrating a gate by a method in accordance with an Example according to an embodiment of the present invention;

FIG. 16 is a graph illustrating the leakage currents in the gate structures of ed according to Comparative Examples 1 to 3; and

FIG. 17 is a graph illustrating the leakage current in the gate structure of the device formed according to the Example described herein according to an embodiment of the present invention.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

The terminology used herein is for the purpose of describing particular embodiments only and is not intended to be limiting of the invention. As used herein, the singular forms “a”, “an ” and “the” are intended to include the plural forms as well, unless the context clearly indicates otherwise. It will be further understood that the terms “comprises” “comprising,” “includes” and/or “including” when used herein, specify the presence of stated features, intergers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

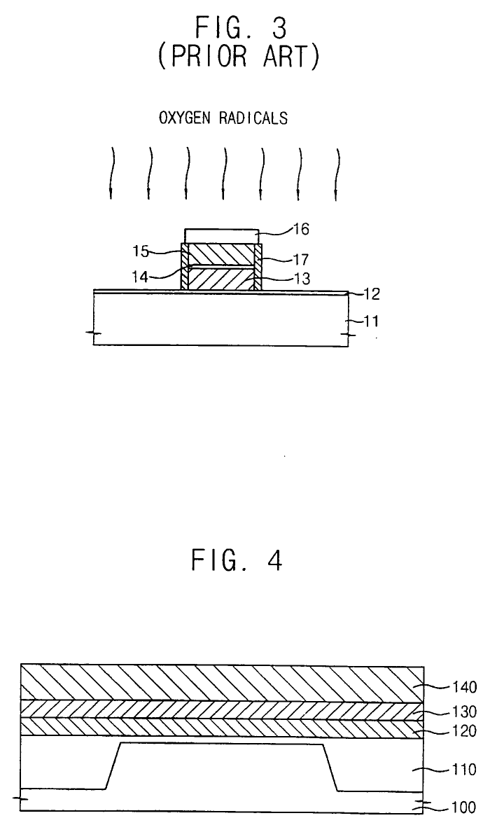

FIGS. 4 to 7 are cross sectional diagrams illustrating methods of manufacturing semiconductor devices in accordance with certain embodiments of the present invention. As shown in FIG. 4, in embodiments of the present invention, a shallow trench isolation (STI) process may be performed on a semiconductor substrate 100 to divide the semiconductor device into an active region and a field region. This may be accomplished, for example, by forming a mask layer (not shown) on the active region, and then etching the semiconductor substrate 100 using the mask layer as an etching mask to form a trench (not shown) in the field region. An insulation layer (not shown) may then be formed on the semiconductor substrate 100 to fill the trench. The upper portion of the insulation layer and the mask layer may then be removed using, for example, a chemical mechanical polishing (CMP) process to expose a surface of the semiconductor substrate 100. The semiconductor substrate 100 may then be thermally oxidized to form a gate oxide layer 110 on the exposed surface of the semiconductor device 100.

As is also shown in FIG. 4, a polysilicon layer 120 may next be formed on the gate oxide layer 110. A metal layer 130 may then be formed on the polysilicon layer 120. The metal layer 130 may be, for example, a tungsten, tungsten silicide, cobalt silicide, nickel silicide or other metal layer. A hard mask layer 140 that includes, for example, silicon nitride, may then be formed on the metal layer 130.

As shown in FIG. 5, the hard mask layer 140, the metal layer 130 and the polysilicon layer 120 may then be partially etched to form a gate structure 160 on the semiconductor device. The gate structure 160 includes the gate oxide layer 110, a polysilicon pattern 122, a metal pattern 132 and a hard mask pattern 142 that are stacked sequentially on the substrate 100.

As noted above, when the etching process that is used to form the gate structure 160 is performed, the gate oxide layer 110 and a channel region of the semiconductor substrate 100 under the gate oxide layer 110 may be damaged so that defects are generated in the gate oxide layer 110 and the channel region. The defects in the channel region in particular may act to deteriorate the operation of the gate.

As shown in FIG. 6, the defects in the channel region and the gate oxide layer 110 may be reduced by annealing the semiconductor substrate 100 at a temperature of about 600° C. or more in an atmosphere that includes, for example, a nitrogen gas, an argon gas, or hydrogen gas or a mixed gas thereof. The use of a relatively high annealing temperature of about 600° C. or more may cause the defects to diffuse such that they are concentrated on surfaces of the channel region and the gate oxide layer 110.

Next, as shown in FIG. 7, oxygen radicals created from, for example, a mixed hydrogen and oxygen source may be applied to the gate structure 160 and the semiconductor substrate 100 at a temperature of no more than about 250° C. Via this process, an oxide layer 152 may be formed that acts as an oxide sidewall on the polysilicon pattern 122 and which effectively increases the thickness of the gate oxide layer 110. The defects that are concentrated on the surfaces of the channel region and the gate oxide layer 110 may readily react with the oxygen radicals so that the defects in the channel region and the gate oxide layer 110 are reduced and/or minimized. By this process, an oxide layer 152 having a desired thickness may be formed on the sidewall of the polysilicon pattern 122.

According to the methods of the above-described embodiments of the present invention, the damaged channel region and the damaged gate oxide layer may be annealed before the oxygen radical oxidation process is performed to provide an oxide layer on the polysilicon pattern that has a desired thickness and to reduce or eliminate the damage to the channel region and the gate oxide layer.

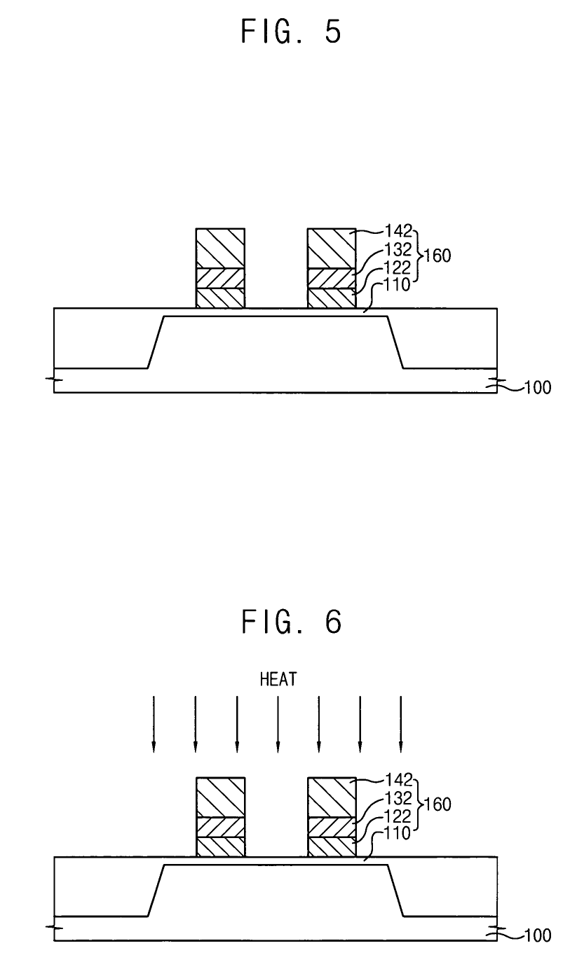

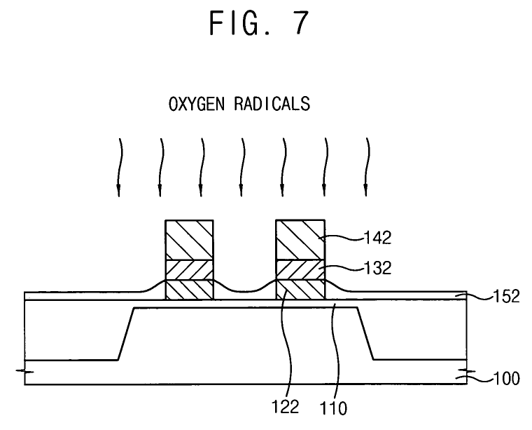

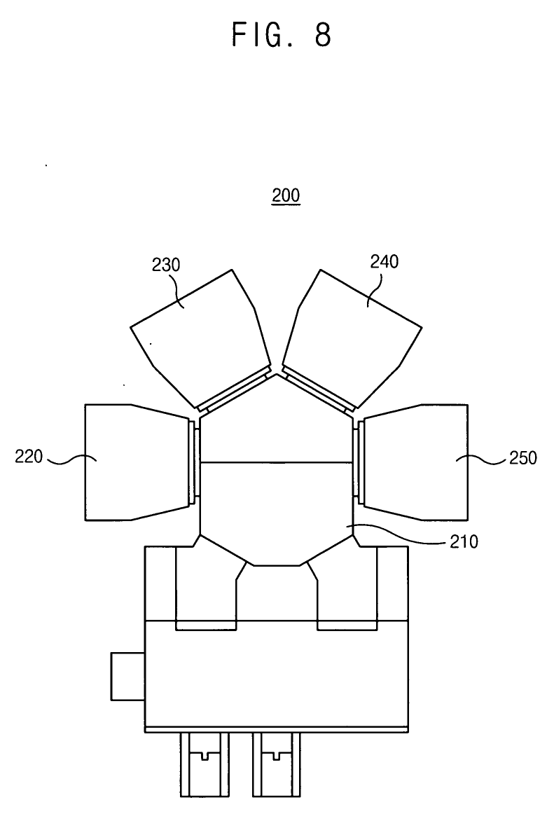

FIG. 8 is a plan view illustrating an apparatus 200 that may be used to manufacture the semiconductor device of FIG. 7 in accordance with one embodiment of the present invention. FIG. 9 is a cross sectional diagram illustrating a first processing unit of the apparatus in FIG. 8, and FIG. 10 is cross sectional diagram illustrating a second processing unit of the apparatus in FIG. 8.

As shown in FIG. 8, the apparatus 200 includes a vacuum chamber 210 into which a vacuum may be introduced, and clustered first, second, third and fourth processing units 220, 230, 240 and 250 that are arranged around the vacuum chamber 210.

The first processing unit 220 may be used to perform an annealing process on a semiconductor substrate having a gate structure. As shown in FIG. 9, the first processing unit 220 may include a chamber 221 into which the semiconductor substrate is loaded, a stage 222, which may be arranged on a bottom face of the chamber 221, that supports the semiconductor substrate, and a lamp 223 or other heating element(s) for providing a heat of no less than about 600° C. to the semiconductor substrate on the stage 222. Examples of the gas that may be introduced into the chamber 221 before and/or during the annealing process are a nitrogen gas, a hydrogen gas, an argon gas or a mixed gas thereof.

The second processing unit 230 may be used to perform an oxidation process on the semiconductor substrate after it is annealed in the first processing unit 220. As shown in FIG. 10, the second processing unit 230 includes a chamber 231 into which the annealed semiconductor substrate is loaded, and a heater 232, which may be arranged on a bottom face of the chamber 231, for supporting the semiconductor substrate and for providing a heat of about, for example, 250° C. to the semiconductor substrate. Oxygen radicals may be introduced into the chamber 231 to perform the oxidation process.

The third processing unit 240 (see FIG. 8) may include elements that are substantially identical to those of the first processing unit 220. The third processing unit 240 may be used to perform an annealing process that is substantially identical to the annealing process described above that may be performed in the first processing unit 220. The fourth processing unit 250 (see FIG. 8) may include elements substantially identical to those of the second processing unit 230. Thus, the fourth processing unit 250 may be used to perform an oxidation process substantially identical to the oxidation process described above that may be performed in the second processing unit 230.

It will be understood that the apparatus 200 having the four processing units 220, 230, 240 and 250 is an exemplarily embodiment of the present invention and that numerous other embodiments/apparatus may be used to perform the methods described herein. The apparatus according to embodiments of the present invention may have at least one unit for performing an annealing process, and at least one unit for performing an oxidation process.

As shown in FIG. 8, the first, second, third and fourth processing units 220, 230, 240 and 250 are connected to each other via the vacuum chamber 210 so that the annealing process and the oxidation process may both be carried out without taking the semiconductor substrate out of the unit (such that the vacuum or other pressure condition is removed).

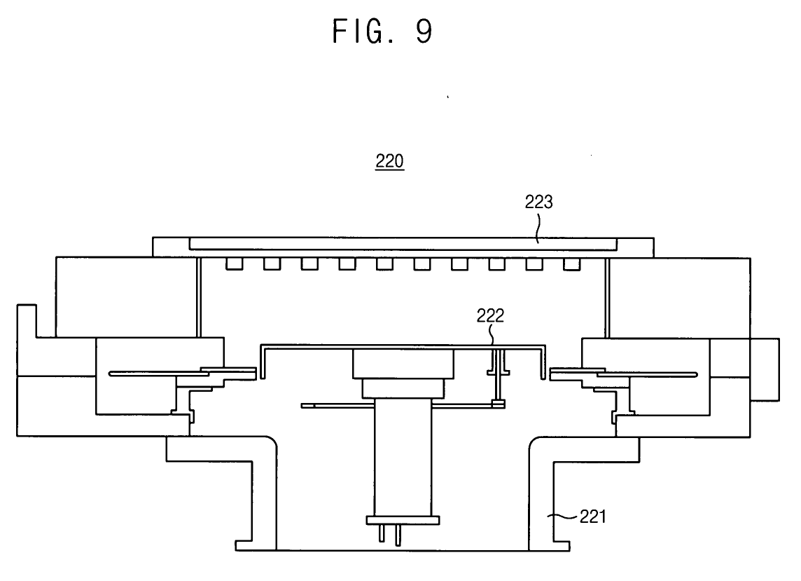

FIG. 11 is a cross sectional diagram illustrating an apparatus 300 that may be used to manufacture the semiconductor device in FIG. 7 in accordance with another embodiment of the present invention. As shown in FIG. 11, the apparatus 300 includes a chamber 310 into which a semiconductor substrate having a gate structure is loaded, a heater 330, which is arranged on a bottom face of the chamber 310, for supporting the semiconductor substrate, and a lamp 320 arranged over the chamber 310.

In the apparatus 300, the lamp 320 may be used to anneal the device to reduce or eliminate damage to the channel region and/or to the gate oxide layer that may have occurred, for example during an etching process. Thus, the lamp 320 may be used to heat the semiconductor substrate to about 600° C. or more. The annealing process may be carried out, for example, in an atmosphere including a nitrogen gas, a hydrogen gas, an argon gas or a mixed gas thereof.

The heater 330 may be used to provide a heat of about 250° C. to an annealed semiconductor substrate to form an oxide layer on sidewalls of the gate structure of, for example, a polysilicon pattern. Oxygen radicals may be introduced into the chamber 310 before and/or during the heating of the semiconductor substrate with the heater 330.

Thus, in the above-described embodiment of the present invention, the annealing process and the oxidation process may both be carried out in the chamber 310. As such, in this embodiment the semiconductor substrate need not be transferred to other processing units.

### EXAMPLE

An oxide layer was formed as follows according to certain embodiments of the present invention. A tunnel oxide layer having a thickness of 61 < was formed on a semiconductor substrate. A first polysilicon layer (which is used to form a floating gate) having a thickness of 700 < was then formed on the tunnel oxide layer. A dielectric layer including oxide/nitride/oxide and having a thickness of 180 < was formed on the first polysilicon layer. A second polysilicon layer (which is used to form a control gate) having a thickness of 500 < was formed on the dielectric layer. A tungsten nitride barrier layer having a thickness of 50 < was formed on the second polysilicon layer. A tungsten layer having a thickness of 315 < was formed on the tungsten nitride barrier layer. A mask oxide layer having a thickness of 1,200 < was then formed on the tungsten layer. The above-mentioned layers were then etched to form a gate structure.

The semiconductor substrate having the gate stricture was then annealed at a temperature of 600° C. under a nitrogen atmosphere. Oxygen radicals were applied to the annealed semiconductor substrate at a temperature of 250° C. under a pressure of 50 mTorr at a power of 3,400 watts to form an oxide layer on a sidewall of the gate stricture.

### COMPARATIVE EXAMPLE 1

An oxide layer was formed using conventional methods as follows. Processes substantially identical those described in the Example above were carried out to form a gate stricture on a semiconductor substrate. Then, the semiconductor substrate having the gate structure was heated at a temperature of 850° C. for 35 minutes in an oxygen atmosphere to form an oxide layer on a sidewall of the gate structure.

### COMPARATIVE EXAMPLE 2

An oxide layer was formed using conventional methods as follows. Processes substantially identical those described in the Example above were carried out to form a gate structure on a semiconductor substrate. Then, the semiconductor substrate having the gate structure was heated at a temperature of 250 to 400° C. under a pressure of 50 mTorr at a power of 3,400 watts to form an oxide layer on a sidewall of the gate structure.

### COMPARATIVE EXAMPLE 3

An oxide layer was formed using conventional methods as follows. Processes substantially identical those described in the Example above were carried out to form a gate structure on a semiconductor substrate. Then, the semiconductor substrate having the gate structure was heated at a temperature of 250° C. under a pressure of 50 mTorr at a power of 3,400 watts to form an oxide layer on a sidewall of the gate structure and the heated semiconductor substrate was annealed at a temperature of 600° C. in a nitrogen atmosphere.

Comparison of SEM Pictures of the Oxide Layers

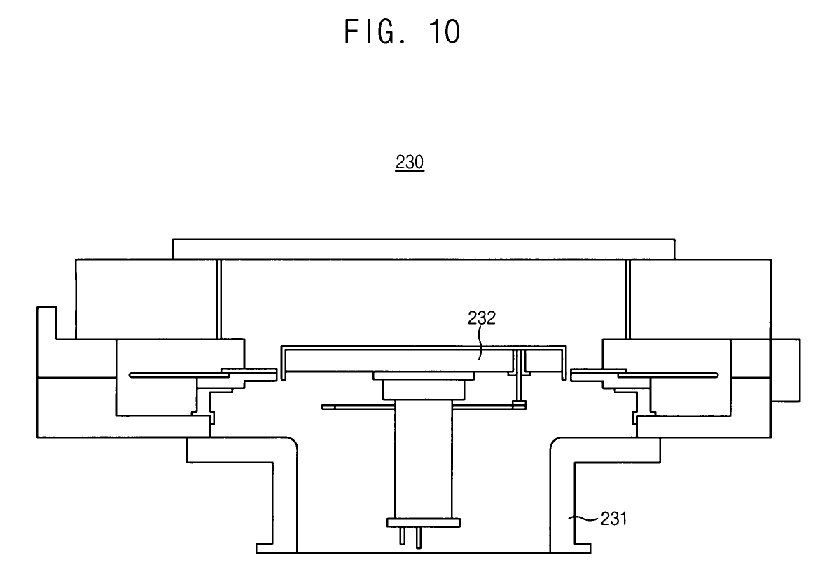

FIG. 12 is a scanning electron microscope (SEM) picture illustrating a gate structure formed using the method described above in Comparative Example 1. As shown in FIG. 12, impurities such as conductive ions are for the most part not present in the sidewall of the tunnel oxide layer. It should be noted that most conductive ions are entirely oxidized in the oxidation process of Comparative Example 1.

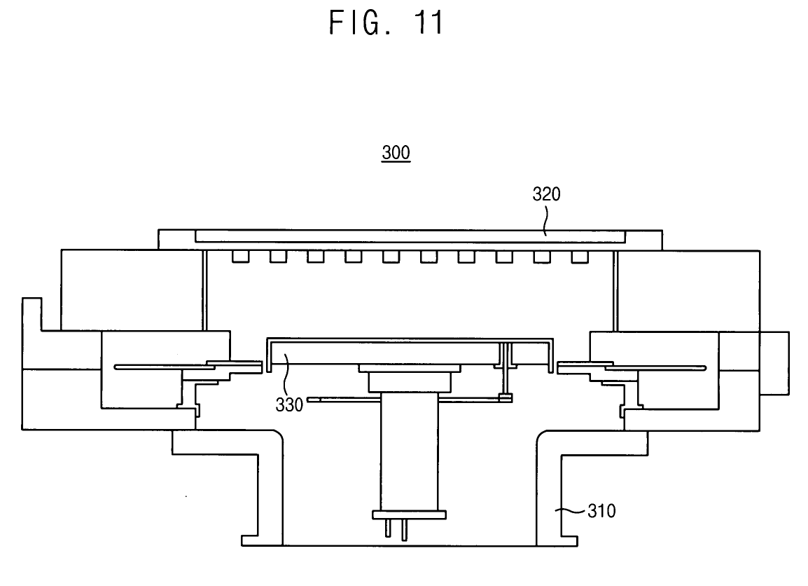

FIG. 13 is a scanning electron microscope (SEM) picture illustrating a gate structure formed by using the method described above in Comparative Example 2. As shown in FIG. 13, impurities (shown in black) such as conductive ions are partially found in the sidewall of the tunnel oxide layer. This indicates that the conductive ions that diffused into the tunnel oxide layer are only partially oxidized in the lower temperature oxidation process of Comparative Example 2.

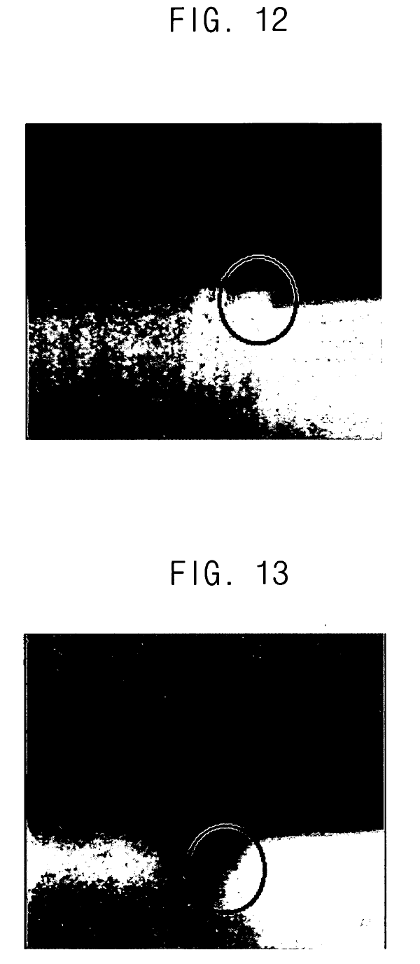

FIG. 14 is a scanning electron microscope (SEM) picture illustrating a gate structure formed by using the method described above in Comparative Example 3. As shown in FIG. 14, impurities such as conductive ions that diffused into the tunnel oxide layer are not entirely oxidized so that the conductive ions are partially found in the sidewall of the tunnel oxide layer. Since the conductive ions are concentratedly distributed over a surface of the tunnel oxide layer when the annealing process is carried out after the oxide layer is formed, the conductive ions in the tunnel oxide layer may not be readily oxidized.

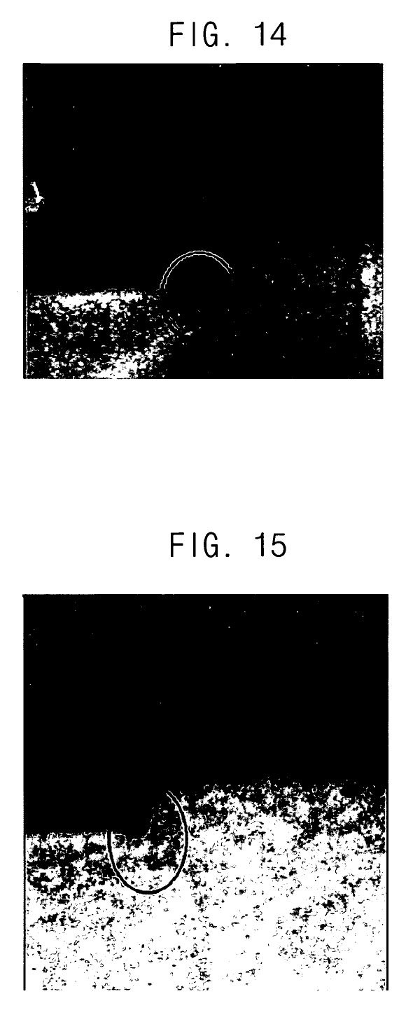

FIG. 15 is a scanning electron microscope (SEM) picture illustrating a gate structure formed by using the method described in the above Example of an embodiment of the present invention. As shown in FIG. 15, few if any conductive ions are found in the sidewall of the tunnel oxide layer. Thus, when the oxidation process is carried out after performing the annealing process for curing the damaged gate structure, most conductive ions in the tunnel oxide layer are oxidized.

Measuring Leakage Current Through the Tunnel Oxide Layers

Leakage currents that flowed through the gate structures of the devices formed in the above Example of an embodiment of the present invention and Comparative Examples 1 to 3 were measured. Here, leakage currents of no more than 1×10⁻¹⁰ ampere were considered normal.

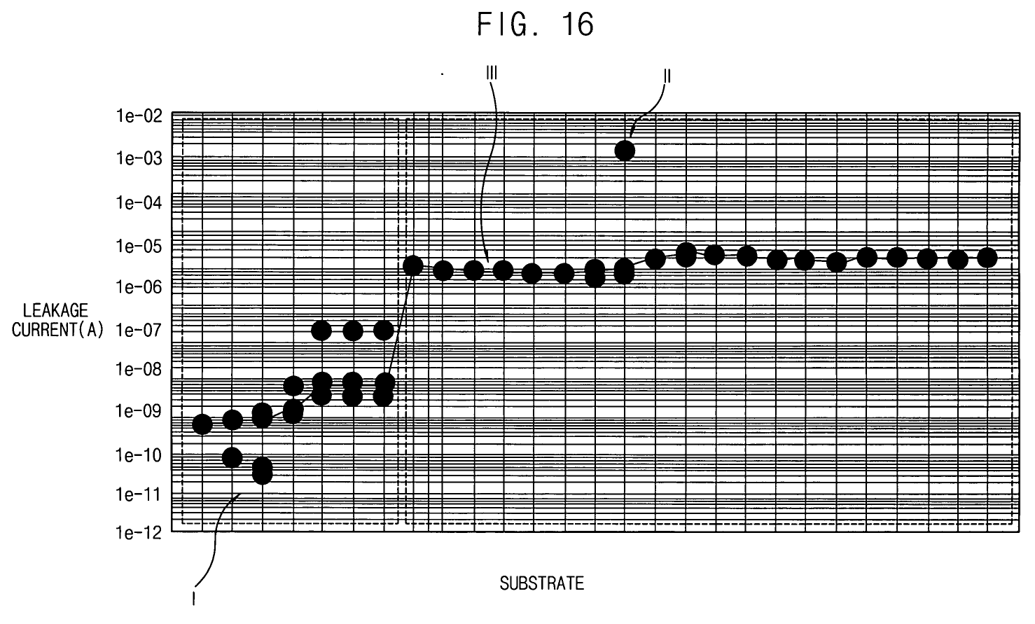

FIG. 16 is a graph illustrating the leakage currents in the gate structures in Comparative Examples 1 to 3. In FIG. 16, points in the region designated “I” represent the leakage currents that were measured through the gate structure obtained in Comparative Example 1. Points in the region designated “II” represent the leakage currents that were measured through the gate structure obtained in Comparative Example 2. Points in the region designated “III” represent the leakage currents that were measured through the gate structure obtained in Comparative Example 3.

As shown in FIG. 12, conductive ions are largely absent from the tunnel oxide layer of the gate structure obtained in Comparative Example 1. Consistent with this finding, the measured leakage current in region I of FIG. 16 is 1×10⁻¹⁰ ampere, which is within the normal range. In contrast, as shown in FIG. 13, a relatively large number of conductive ions are found in the tunnel oxide layer of the gate structure obtained in Comparative Example 2. Consistent with this finding, the measured leakage current in region II of FIG. 16 is 1×10^{31 3} ampere, which is beyond the normal range. Similarly, as shown in FIG. 14, a relatively large number of conductive ions are found in the tunnel oxide layer of the gate structure obtained in Comparative Example 3. Consistent with this finding, the measured leakage current in region III of FIG. 16 is 1×10⁻⁶ ampere, which also is beyond the normal range.

As shown in FIG. 16, a relatively large amount of leakage current flows through the conventional gate structures of Comparative Examples 2 and 3, which are the comparative examples in which the oxygen radical oxidation process were used. The gate structure of Comparative Example 3 provides improved performance as compared to Comparative Example 2, through the use of an additional annealing process that is carried out after performing the oxidation process using the oxygen radicals only provides a relatively small reduction in the leakage currents, and does not bring the leakage currents into the normal range. One reason for this may be that since the re-oxidation process in the conventional methods is performed at a temperature of about 250° C. to about 400° C., the defects may not diffuse to the surface of the channel region. As a result, the channel region may not be completely repaired. When the high-temperature thermal treatment is carried out, the remaining defects may diffuse into the surface of the channel region. However, since the high-temperature thermal treatment is performed in an oxygen-free atmosphere, these defects are not oxidized.

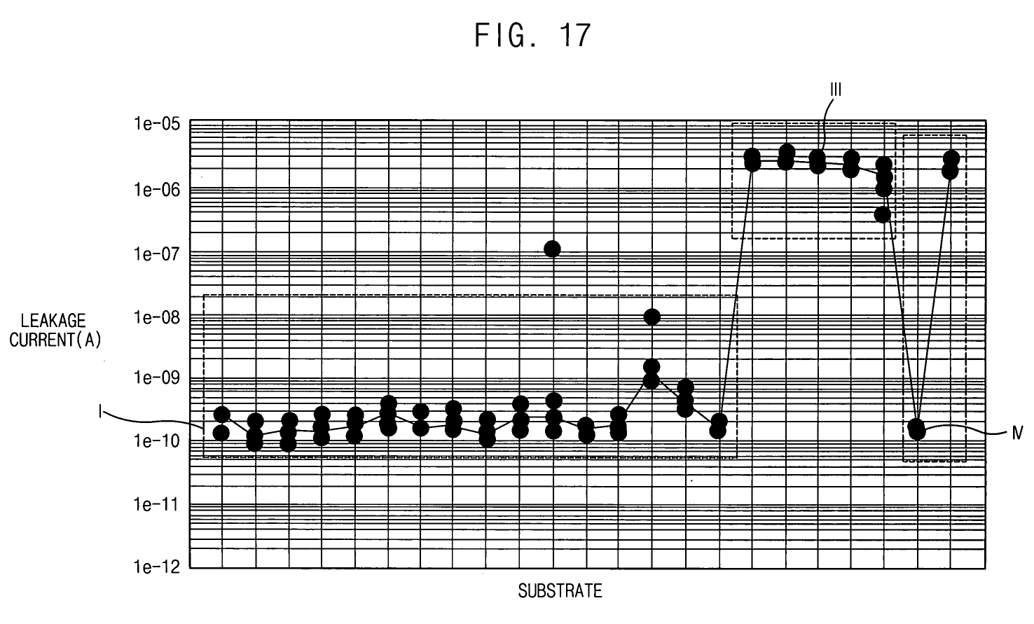

FIG. 17 is a graph illustrating the leakage current measured in the gate structure formed in the above described Example according to embodiments of the present invention. In FIG. 17, points in the region designated “IV” represent the leakage currents measured in the gate structure obtained in the Example.

As shown in FIG. 15, almost no conductive ions are found in the tunnel oxide layer of the gate structure obtained in the Example, similar to the results found with Comparative Example 1. Consistent with this, the measured leakage current in region IV of FIG. 17 is 1×10⁻¹⁰ ampere, which is within the normal range.

When the oxidation process is carried out after performing the annealing process in accordance with embodiments of the present invention, the measured results show that the leakage currents through the gate structure may be within the normal range, as shown in FIG. 17. This shows that the conductive ions diffusing into the tunnel oxide layer may be concentrated on the surfaces of the damaged layers by the annealing process and may then largely be oxidized by the oxidation process.

According to embodiments of the present invention, after the annealing process is carried out to cure the damage to the channel region and the gate oxide layer, the oxidation process is performed. As a result, an oxide layer having desired characteristics and thickness may be formed on the gate structure, thereby improving reliability with respect to the operation of the gate.

In the drawings and specification, there have been disclosed typical embodiments of the invention and, although specific terms are employed, they are used in a generic and descriptive sense only and not for purposes of limitation, the scope of the invention being set forth in the following claims.

1. A method of manufacturing a semiconductor device, the method comprising:
forming a gate structure having a conductive pattern on a substrate;
annealing the gate structure having a conductive pattern to provide an annealed gate structure; and
applying oxygen radicals to the annealed gate structure to form an oxide layer on a sidewall of the conductive pattern.

2. The method of claim 1, wherein forming the gate structure comprises:
forming a gate oxide layer on the substrate; and
forming the conductive pattern on the gate oxide layer.

3. The method of claim 2, wherein forming the conductive pattern comprises:
forming a polysilicon pattern on the gate oxide layer;
forming a metal pattern on the polysilicon pattern; and
forming a hard mask pattern on the metal pattern;
wherein the oxide layer is formed on a sidewall of the polysilicon pattern.

4. The method of claim 3, wherein the metal pattern comprises tungsten, tungsten silicide, cobalt silicide or nickel silicide.

5. The method of claim 3, wherein the hard mask pattern comprises tungsten nitride.

6. The method of claim 1, wherein annealing the gate structure comprises annealing the gate structure at a temperature of no less than about 600° C.

7. The method of claim 1, wherein annealing the gate structure comprises annealing the gate structure at a temperature of no less than about 600° C. in an atmosphere including at least one of a nitrogen gas, a hydrogen gas, and/or an argon gas.

8. The method of claim 1, wherein applying oxygen radicals to the gate structure comprises applying oxygen radicals to the gate structure at a temperature of no more than about 250° C. to form an oxide layer on a sidewall of the conductive pattern.

9. The method of claim 1, wherein annealing the gate structure and forming the oxide layer are performed in-situ under vacuum.

10. A method of forming a gate comprising:
forming a gate oxide layer on a substrate;
sequentially forming a polysilicon layer, a tungsten layer and a tungsten nitride layer on the gate oxide layer;
patterning the polysilicon layer, the tungsten layer and the tungsten nitride layer to form a gate structure including a polysilicon pattern, a tungsten pattern and a tungsten nitride pattern;
annealing the gate structure in an atmosphere that includes at least one inert gas; and
applying oxygen radicals to the annealed gate structure to form an oxide layer on a sidewall of the polysilicon pattern.

11. The method of claim 10, wherein the annealing is performed at least one first temperature, and wherein the oxygen radicals are applied at least one second temperature that is lower than the first temperature.

12. The method of claim 11, wherein the first temperature is no less than about 600° C., and the second temperature is no more than about 250° C.

13. A method of manufacturing a semiconductor device, the method comprising:
heating an annealing unit to a first temperature using a lamp located within the annealing unit;
annealing a gate structure that has been formed on a substrate in the annealing unit at the first temperature; and then
applying oxygen radicals to the gate structure at a second temperature that is lower than the first temperature to form an oxide layer on a sidewall of the conductive pattern.

14. The method of claim 13, wherein the oxygen radicals are applied to the gate structure in a re-oxidation unit that is separate from the annealing unit.

15. The method of claim 14, wherein applying oxygen radicals to the gate stricture comprises applying oxygen radicals to the gate structure in the re-oxidation unit after heating the re-oxidation unit to the second temperature using a heater.

16. The method of claim 13, further comprising transferring the gate structure that has been formed on the substrate from the annealing unit after the annealing is completed to the re-oxidation unit for application of the oxygen radicals via a vacuum chamber that is coupled between the annealing unit and the re-oxidation unit.

17. The method of claim 16, wherein applying oxygen radicals to the gate structure at a second temperature that is lower than the first temperature to form an oxide layer on a sidewall of the conductive pattern comprises heating the annealing unit to the second temperature using a heater arranged at a lower portion of the chamber and then applying oxygen radicals to the gate structure.

18. An apparatus for manufacturing a semiconductor device comprising:
a heating unit that is configured to anneal a gate structure having a conductive pattern at a first temperature; and
a re-oxidation unit that is configured to apply oxygen radicals to the gate structure at a second temperature that is lower than the first temperature to form an oxide layer on a sidewall of the conductive pattern.

19. The apparatus of claim 18, wherein the heating unit includes a lamp that is configured to heat the heating unit to the first temperature.

20. The apparatus of claim 18, wherein the re-oxidation unit includes a heater configured to heat the heating unit to the second temperature.

21. The apparatus of claim 18, further comprising a vacuum chamber connected between the heating unit and the re-oxidation unit.

22. The apparatus of claim 21, wherein the re-oxidation unit is configured to receive the gate structure from the heating unit via the vacuum chamber.

23. An apparatus for manufacturing a semiconductor device comprising:
a chamber for receiving a substrate on which a gate structure having a conductive pattern is formed;
a lamp arranged over the chamber that is configured to heat the substrate to a first temperature for annealing the gate structure; and
a heater arranged at a lower portion of the chamber and supporting the substrate that is configured to heat an annealed gate structure to a second temperature that is lower than the first temperature for forming an oxide layer on a sidewall of the conductive pattern.
